(19) United States
(12) Patent Application Publication
(10) Pub. No.: US 2023/0150067 A1
(43) Pub. Date: May 18, 2023

(54) LASER MACHINING DEVICE AND LASER MACHINING METHOD

(71) Applicant: HAMAMATSU PHOTONICS K.K., Hamamatsu-shi, Shizuoka (JP)

(72) Inventor: Katsuhiro KOREMATSU, Hamamatsu-shi, Shizuoka (JP)

(73) Assignee: HAMAMATSU PHOTONICS K.K., Hamamatsu-shi, Shizuoka (JP)

(21) Appl. No.: 17/916,824

(22) PCT Filed: Mar. 31, 2021
(86) PCT No.: PCT/JP2021/013838

§ 371 Date: Oct. 4, 2022

(30) Foreign Application Priority Data
Apr. 6, 2020 (JP) 2020-068422

(51) Int. Cl. B23K 26/53; B23K 26/06; B23K 26/073

(52) U.S. Cl. CPC B23K 26/53; B23K 26/0648; B23K 26/073

(57) ABSTRACT

Provided is a laser processing device for forming a modified region by irradiating an object with laser light. The device includes a support portion configured to support the object, a laser irradiation unit configured to irradiate the object supported by the support portion with the laser light, a moving mechanism that moves at least one of the support portion and the laser irradiation unit such that a converging point of the laser light relatively moves with respect to the object, and a control unit that controls the laser irradiation unit and the moving mechanism. A first line extending along a first direction and a second line extending along a second direction intersecting the first direction and extending beyond the first line when viewed from a direction intersecting an incident surface of the laser light are set in the object.

### TECHNICAL FIELD

One aspect of the present disclosure relates to a laser processing device and a laser processing method.

### BACKGROUND ART

Patent Literature 1 describes a laser processing device. Such a laser processing device includes a condenser lens, and forms a processed layer on a single crystal member by laser light emitted from the condenser lens. The condenser lens includes a sub condenser system on which laser light is incident and a main condenser system on which the laser light emitted from the sub condenser system is incident and which irradiates the single crystal member with the laser light. The sub condenser system includes a cylindrical lens array body in which a plurality of cylindrical lenses is integrally arranged, and a cylindrical convex lens through which light from the cylindrical lens array body passes.

In such a laser processing device, the laser light incident on the cylindrical lens is branched into a plurality of beams, and then enters the cylindrical convex lens while forming a converging point, and an irradiating surface becomes an elongated parallel beam and enters the main condenser system. The laser light emitted from the main condenser system is incident as branched laser light on an irradiated surface of the single crystal member to form a plurality of converging points inside the single crystal member.

### CITATION LIST

### Patent Literature

Patent Literature 1: Japanese Unexamined Patent Publication No. 2014 -19120 A

### SUMMARY OF INVENTION

### Technical Problem

In the laser processing device described above, the processed layer is formed while forming a plurality of converging points of the laser light, thereby improving the formation speed of the processed layer. That is, in the above technical field, it is desired to improve processing speed. On the other hand, according to findings by the inventors of the present invention, when laser light is irradiated to simultaneously form a plurality of converging points in the thickness direction of an object, a crack extending from a modified region formed at one converging point affects formation of modified regions at the other converging points and development of the cracks, and as a result, there is a possibility that crack amount (length of the crack) becomes unstable. When the crack amount becomes unstable, quality (that is, processing quality) of a cut surface when the object is cut with the crack as a boundary is deteriorated.

The crack amount tends to be relatively small in the vicinity of the irradiation start position of the laser light and relatively large at a position advanced to some extent from the irradiation start position. In addition, in a case where the laser light is irradiated so as to straddle an already formed modified region and the like (a modified region and a crack extending from the modified region), similarly to the relationship with the irradiation start position, the crack amount tends to be relatively small in the vicinity of the modified region and the like, and the crack amount tends to be relatively large at a position advanced from the modified region and the like to some extent.

Therefore, for example, in a case where the entire object before formation of the modified region or the like is irradiated with the laser light, the crack amount is constant at a relatively large level in most of the area except for the vicinity of the irradiation start position, and thus, the influence of destabilization of the entire crack amount on the processing quality is relatively small.

On the other hand, in a case where the object is irradiated with the laser light so as to straddle the modified region or the like already formed along a second direction different from a first direction after the modified region or the like is formed along the first direction, since a portion where the crack amount decreases and a portion where the crack amount increases repeatedly occur in a short period (a pitch of formation of the modified region or the like in the second direction) as compared with the entire object, the influence of destabilization of the entire crack amount on the processing quality is relatively large. Therefore, in such a case, it is important to suppress deterioration of the processing quality by suppressing the destabilization of the crack amount.

Therefore, an object of one aspect of the present disclosure is to provide a laser processing device and a laser processing method capable of achieving both improvement in processing speed and suppression of deterioration in processing quality.

### Solution to Problem

A laser processing device according to one aspect of the present disclosure is a laser processing device for forming a modified region by irradiating an object with laser light, the laser processing device including: a support portion configured to support the object; a laser irradiation unit configured to irradiate the object supported by the support portion with the laser light; a moving mechanism configured to move at least one of the support portion and the laser irradiation unit such that a converging point of the laser light relatively moves with respect to the object; and a control unit configured to control the laser irradiation unit and the moving mechanism, in which a first line extending along a first direction and a second line extending along a second direction intersecting the first direction and extending beyond the first line when viewed from a direction intersecting an incident surface of the laser light are set in the object, and the control unit performs, by controlling the laser irradiation unit and the moving mechanism, a first process of forming the modified region along the first line by irradiating the object with the laser light while relatively moving the converging point along the first line, performs, after the first process, by controlling the laser irradiation unit and the moving mechanism, a second process of forming the modified region along the second line by irradiating the object with the laser light while forming a first converging point of the laser light and a second converging point of the laser light located closer to an incident surface side of the object than the first converging point and at the same time relatively moving the first converging point and the second converging point along the second line so that a crack extending from the modified region formed at the first converging point and a crack extending from the modified region formed at the second converging point are not connected to each other, and performs, after the second process, by controlling the laser irradiation unit and the moving mechanism, a third process of forming the modified region along the second line at a third position between a first position of the first converging point and a second position of the second converging point in a direction intersecting the incident surface and forming a crack over the modified region formed at the first position and the modified region formed at the second position by irradiating the object with the laser light while forming a third converging point of the laser light at the third position and at the same time relatively moving the third converging point along the second line.

A laser processing method according to one aspect of the present disclosure is a laser processing method for forming a modified region by irradiating an object with laser light, the laser processing method including a laser light irradiation step of irradiating the object with the laser light while relatively moving a converging point of the laser light with respect to the object to form the modified region, in which a first line extending along a first direction and a second line extending along a second direction intersecting the first direction and extending beyond the first line when viewed from a direction intersecting an incident surface of the laser light are set in the object, and the laser light irradiation step includes: a first step of forming the modified region along the first line by irradiating the object with the laser light while relatively moving the converging point along the first line; a second step of forming, after the first step, the modified region along the second line by irradiating the object with the laser light while forming a first converging point of the laser light and a second converging point of the laser light located closer to an incident surface side of the object than the first converging point and at the same time relatively moving the first converging point and the second converging point along the second line so that a crack extending from the modified region formed at the first converging point and a crack extending from the modified region formed at the second converging point are not connected to each other; and a third step of forming, after the second step, the modified region along the second line at a third position between a first position of the first converging point and a second position of the second converging point in a direction intersecting the incident surface and forming a crack over the modified region formed at the first position and the modified region formed at the second position by irradiating the object with the laser light while forming a third converging point of the laser light at the third position and at the same time relatively moving the third converging point along the second line.

In the device and the method according to one aspect of the present disclosure, the first line extending along the first direction and the second line extending along the second direction intersecting the first direction and extending beyond the first line are set in the object. After the modified region is formed by irradiation with the laser light along the first line, the modified region is formed by irradiation with the laser light along the second line. At the time of irradiation with the laser light along the second line, at least two converging points are formed in the direction intersecting the incident surface of the laser light of the object. Therefore, the processing speed is improved. On the other hand, in the device and the method according to one aspect of the present disclosure, the irradiation of the laser light is generated so as to straddle the modified region and the like already formed along the first line. Therefore, it is important to suppress the destabilization of the crack.

Here, according to findings by the inventors of the present invention, in a case where laser light is irradiated while forming a first converging point and a second converging point in a direction intersecting an incident surface of laser light on an object, if a modified region corresponding to another third converging point is formed between a position of the first converging point and a position of the second converging point after forming modified regions corresponding to the first converging point and the second converging point so that a crack extending from the modified region formed at the first converging point and a crack extending from the modified region formed at the second converging point are not connected to each other, thereby forming a crack over the modified region corresponding to the first converging point and the modified region corresponding to the second converging point, it is possible to suppress the destabilization of the entire crack amount.

Therefore, in the device and the method according to one aspect of the present disclosure, after the modified region is formed along the first line, first, the modified region is formed along the second line by irradiating the object with the laser light while relatively moving the first converging point and the second converging point along the second line so that a crack extending from the modified region formed at the first converging point of the laser light and a crack extending from the modified region formed at the second converging point of the laser light are not connected to each other. Thereafter, a modified region is formed along the second line at a third position between the first position of the first converging point and the second position of the second converging point and a crack is formed over the modified region formed at the first position and the modified region formed at the second position by irradiating the object with the laser light while forming a third converging point of the laser light at the third position and at the same time relatively moving the third converging point along the second line. As a result, as the findings described above, destabilization of the entire crack amount is suppressed. Therefore, deterioration in processing quality is suppressed.

In the laser processing device according to one aspect of the present disclosure, in the second process, the control unit may position, by controlling the laser irradiation unit, the first converging point in front of the second converging point in the relative movement direction of the first converging point and the second converging point. In such a case, the extension amount of the crack from the modified region formed at each of the first converging point and the second converging point can be increased. As a result, the number of rows of required modified regions is reduced in the direction intersecting the incident surface of the laser light on the object, and the processing speed is improved.

In the laser processing device according to one aspect of the present disclosure, in the second process, the control unit may cause, by controlling the laser irradiation unit, the first converging point and the second converging point to coincide with each other in the relative movement direction of the first converging point and the second converging point. In such a case, the extension amount of the crack from the modified region formed at each of the first converging point and the second converging point can be reduced. As a result, it is possible to reliably suppress connection between the crack extending from the modified region formed by the first converging point and the crack extending from the modified region formed by the second converging point.

In the laser processing device according to one aspect of the present disclosure, in the third process, the control unit may irradiate, by controlling the laser irradiation unit and the moving mechanism, the object with the laser light while forming the third converging point and the fourth converging point of the laser light located closer to the incident surface side than the third converging point and at the same time relatively moving the third converging point and the fourth converging point along the second line. In such a case, the processing speed is further improved.

In the laser processing device according to one aspect of the present disclosure, in the first process, the control unit may irradiate, by controlling the laser irradiation unit and the moving mechanism, the object with the laser light while forming a fifth converging point of the laser light and a sixth converging point of the laser light located closer to the incident surface side of the object than the fifth converging point and at the same time relatively moving the fifth converging point and the sixth converging point along the first line. In such a case, the processing speed is further improved.

In the laser processing device according to one aspect of the present disclosure, in the first process, the control unit may perform, by controlling the laser irradiation unit and the moving mechanism, a fourth process of forming the modified region along the first line by irradiating the object with the laser light while relatively moving the fifth converging point and the sixth converging point along the first line so that a crack extending from the modified region formed at the fifth converging point and a crack extending from the modified region formed at the sixth converging point are not connected to each other, and perform, after the fourth process, by controlling the laser irradiation unit and the moving mechanism, a fifth process of forming the modified region along the first line at a seventh position between a fifth position of the fifth converging point and a sixth position of the sixth converging point in a direction intersecting the incident surface and forming a crack over the modified region formed at the fifth position and the modified region formed at the sixth position by irradiating the object with the laser light while forming a seventh converging point of the laser light at the seventh position and at the same time relatively moving the seventh converging point along the first line. In such a case, for the same reason as described above, it is possible to improve the processing speed and suppress deterioration in processing quality also in the first process.

A laser processing device according to one aspect of the present disclosure is a laser processing device for forming a modified region by irradiating an object with laser light, the laser processing device including: a support portion configured to support the object; a laser irradiation unit configured to irradiate the object supported by the support portion with the laser light; a moving mechanism configured to move at least one of the support and the laser irradiation unit such that a converging point of the laser light relatively moves with respect to the object; and a control unit configured to control the laser irradiation unit and the moving mechanism, in which the control unit performs, by controlling the laser irradiation unit and the moving mechanism, a process of forming the modified region along a line by irradiating the object with the laser light while forming a first converging point of the laser light and a second converging point of the laser light located closer to an incident surface side of the laser light on the object than the first converging point and at the same time relatively moving the first converging point and the second converging point along the line so that a crack extending from the modified region formed at the first converging point and a crack extending from the modified region formed at the second converging point are not connected to each other, and performs, after the above process, by controlling the laser irradiation unit and the moving mechanism, another process of forming the modified region along a line at a third position between a first position of the first converging point and a second position of the second converging point in a direction intersecting the incident surface and forming a crack over the modified region formed at the first position and the modified region formed at the second position by irradiating the object with the laser light while forming a third converging point of the laser light at the third position and at the same time relatively moving the third converging point along the line.

In such a laser processing device, the modified region is formed by irradiating the object with the laser light while relatively moving the first converging point and the second converging point such that a crack extending from the modified region formed at the first converging point of the laser light and a crack extending from the modified region formed at the second converging point of the laser light are not connected to each other. Thereafter, a modified region is formed at a third position between the first position of the first converging point and the second position of the second converging point and a crack is formed over the modified region formed at the first position and the modified region formed at the second position by irradiating the object with the laser light while forming a third converging point of the laser light at the third position and at the same time relatively moving the third converging point. As a result, as the findings described above, destabilization of the crack amount is suppressed. Therefore, deterioration in processing quality is suppressed.

### Advantageous Effects of Invention

According to one aspect of the present disclosure, it is possible to provide a laser processing device and a laser processing method capable of achieving both improvement in processing speed and suppression of deterioration in processing quality.

### BRIEF DESCRIPTION OF DRAWINGS

FIG. 1 is a schematic view illustrating a configuration of a laser processing device according to an embodiment.

FIG. 2 is a schematic view illustrating a configuration of a laser irradiation unit illustrated in FIG. 1.

FIG. 3 is a schematic view illustrating a configuration of the laser irradiation unit illustrated in FIG. 1.

FIG. 4 is a cross-sectional view illustrating processing according to a first example.

FIG. 5 is a cross-sectional photograph showing a processing result according to the first example.

FIG. 6 is a cross-sectional view illustrating processing according to a second example.

FIG. 7 is a cross-sectional photograph showing a processing result according to the second example.

FIG. 8 is a flowchart illustrating an example of a laser processing method according to the present embodiment.

FIG. 9 is a view illustrating one step of the laser processing method illustrated in FIG. 8.

FIG. 10 is a view illustrating one step of the laser processing method illustrated in FIG. 8.

FIG. 11 is a view illustrating one step of the laser processing method illustrated in FIG. 8.

FIG. 12 is a diagram illustrating an example of a setting screen displayed on an input receiving unit.

FIG. 13 is a view illustrating one step of the laser processing method illustrated in FIG. 8.

FIG. 14 is a view illustrating one step of the laser processing method illustrated in FIG. 8.

FIG. 15 is a view illustrating one step of the laser processing method illustrated in FIG. 8.

### DESCRIPTION OF EMBODIMENTS

Hereinafter, an embodiment will be described in detail with reference to the drawings. In the drawings, the same or corresponding portions are denoted by the same reference numerals, and redundant description may be omitted. In addition, each drawing may illustrate an orthogonal coordinate system defined by an X axis, a Y axis, and a Z axis.

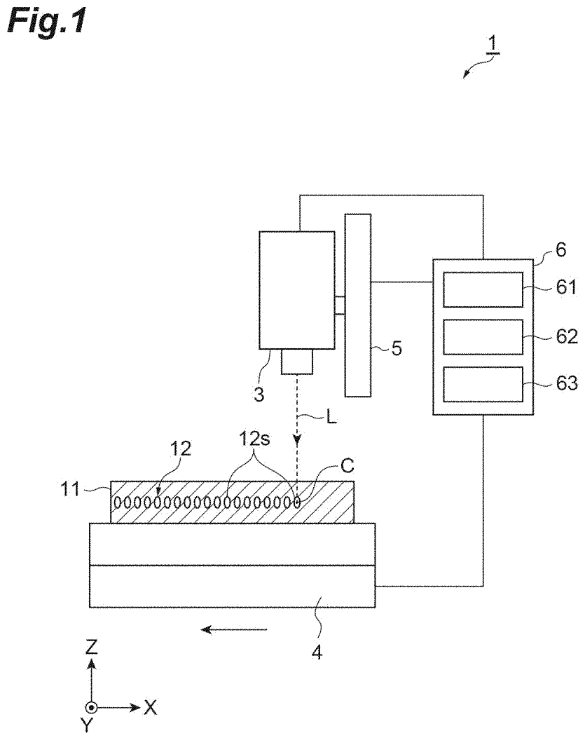

FIG. 1 is a schematic view illustrating a configuration of a laser processing device according to the embodiment. As illustrated in FIG. 1, a laser processing device 1 includes a stage (support portion) 2, a laser irradiation unit 3, drive units (moving mechanisms) 4 and 5, and a control unit 6. The laser processing device 1 is a device for forming a modified region 12 in an object 11 by irradiating the object 11 with laser light L.

The stage 2 supports the object 11, for example, by holding a film attached to the object 11. The stage 2 is rotatable about an axis parallel to a Z direction as a rotation axis. The stage 2 may be movable along each of an X direction and a Y direction. The X direction and the Y direction are a first horizontal direction and a second horizontal direction intersecting (orthogonal to) each other, and the Z direction is a vertical direction.

The laser irradiation unit 3 condenses the laser light L having transparency with respect to the object 11 and irradiates the object 11 with the laser light L. When the laser light L is converged inside the object 11 supported by the stage 2, the laser light L is particularly absorbed in a portion corresponding to a converging point C of the laser light L, so that the modified region 12 is formed inside the object 11.

The modified regions 12 are regions that differ from the surrounding unmodified regions in density, refractive index, mechanical strength, and other physical properties. Examples of the modified region 12 include a melting treatment region, a crack region, a dielectric breakdown region, and a refractive index change region. The modified region 12 may be formed such that a crack extends from the modified region 12 to an incident side of the laser light L and the opposite side thereof. Such modified region 12 and crack are utilized, for example, to cut the object 11.

As an example, when the stage 2 is moved along the X direction and the converging point C is moved relative to the object 11 along the X direction, a plurality of modified spots 12s are formed so as to be arranged in a row along the X direction. One modified spot 12s is formed by irradiation with one pulse of laser light L. One row of modified region 12 is a set of the plurality of modified spots 12s arranged in one row. The adjacent modified spots 12s may be connected to each other or may be separated from each other depending on the relative moving speed of the converging point C with respect to the object 11 and the repetition frequency of the laser light L.

The drive unit 4 rotates the stage 2 about an axis parallel to the Z direction as a rotation axis. The drive unit 4 may move the stage 2 along each of the X direction and the Y direction. The drive unit 5 supports the laser irradiation unit 3. The drive unit 5 moves the laser irradiation unit 3 along the X direction, the Y direction, and the Z direction. By moving the stage 2 and/or the laser irradiation unit 3 in a state where the converging point C of the laser light L is formed, the converging point C is moved relative to the object 11. That is, the drive units 4 and 5 are moving mechanisms that move at least one of the stage 2 and the laser irradiation unit 3 such that the converging point C of the laser light L moves relative to the object 11.

The control unit 6 controls the operations of the stage 2, the laser irradiation unit 3, and the drive units 4 and 5. The control unit 6 includes a processing unit 61, a storage unit 62, and an input receiving unit (display unit, input unit) 63. The processing unit 61 is configured as a computer device including a processor, a memory, a storage, a communication device, and the like. In the processing unit 61, the processor executes software (program) read in the memory or the like, and controls reading and writing of data in the memory and the storage and communication by the communication device. The storage unit 62 is, for example, a hard disk or the like, and stores various data. The input receiving unit 63 is an interface unit that displays various types of information and receives inputs of various types of information from the user. In the present embodiment, the input receiving unit 63 constitutes a graphical user interface (GUI).

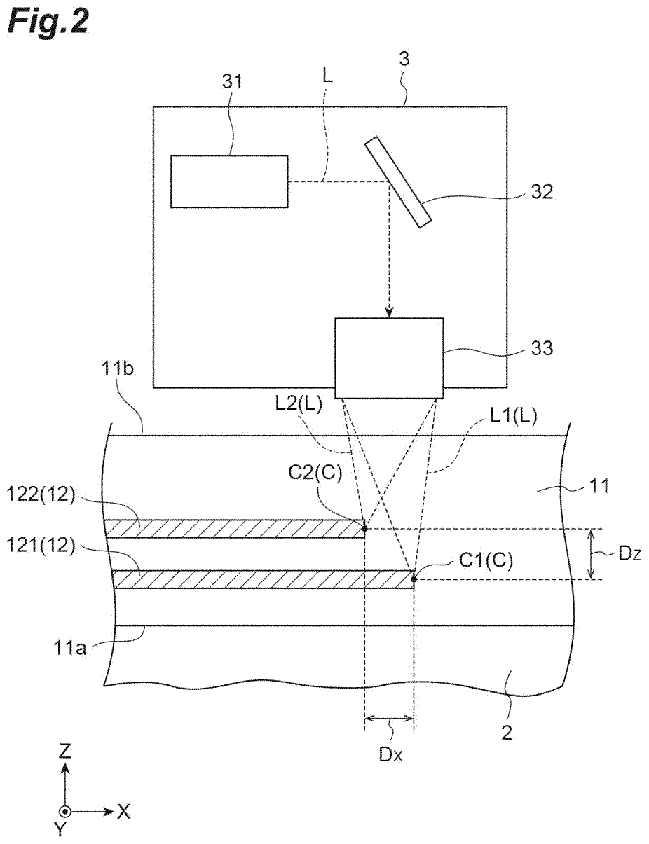

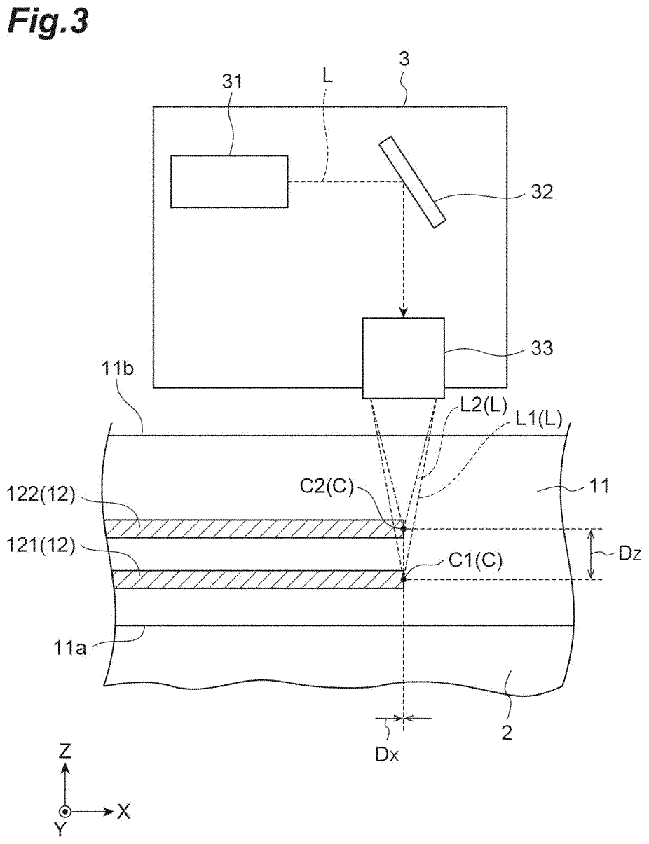

FIGS. 2 and 3 are schematic views illustrating a configuration of the laser irradiation unit illustrated in FIG. 1. As illustrated in FIGS. 2 and 3, the laser irradiation unit 3 includes a light source 31, a spatial light modulator 32, and a condenser lens 33. The light source 31 outputs the laser light L by, for example, a pulse oscillation method. Note that the laser irradiation unit 3 may not include the light source 31 and may be configured to introduce the laser light L from the outside of the laser irradiation unit 3.

The spatial light modulator 32 modulates the laser light L output from the light source 31. The spatial light modulator 32 is a spatial light modulator (SLM) of a reflective liquid crystal on silicon (LCOS). The condenser lens 33 condenses the laser light L modulated by the spatial light modulator 32. The spatial light modulator 32 includes a liquid crystal layer (not illustrated), and modulates the laser light L according to a modulation pattern displayed on the liquid crystal layer. Here, the spatial light modulator 32 displays a branching pattern for branching at least the laser light L into a plurality of (here, two) beams. As a result, the laser light L incident on the spatial light modulator 32 is branched into two laser lights L1 and L2 in the spatial light modulator 32 and is converged by the condenser lens 33 to form a converging point C1 and a converging point C2.

This point will be described more specifically. The spatial light modulator 32 branches the laser light L such that the converging point C1 and the converging point C2 are formed at positions different from each other at least in the Z direction intersecting a back surface 11b that is the incident surface of the laser light L on the object 11. Therefore, by relatively moving the converging point C1 and the converging point C2 with respect to the object 11, two rows of modified region 121 and modified region 122 are formed as the modified region 12 at positions different from each other in the Z direction.

The modified region 121 corresponds to the laser light L1 and the converging point C1 thereof, and the modified region 122 corresponds to the laser light L2 and the converging point C2 thereof. The converging point C1 and the modified region 121 are located on the opposite side to the back surface 11b (a front surface 11a side of the object 11) with respect to the converging point C2 and the modified region 122. In the spatial light modulator 32, a distance Dz (vertical branch amount) between the converging point C1 and the converging point C2 in the Z direction is made variable by adjusting the branching pattern.

Furthermore, when branching the laser light L into the laser lights L1 and L2, the spatial light modulator 32 can change a distance Dx (lateral branch amount) in a horizontal direction (X direction in the illustrated example) between the converging point C1 and the converging point C2. In the example of FIG. 2, the spatial light modulator 32 sets the distance Dx to be larger than 0 such that the converging point C1 is located in front of the converging point C2 in the X direction (processing traveling direction). In the example of FIG. 3, the spatial light modulator 32 sets the distance Dx between the converging point C1 and the converging point C2 to 0.

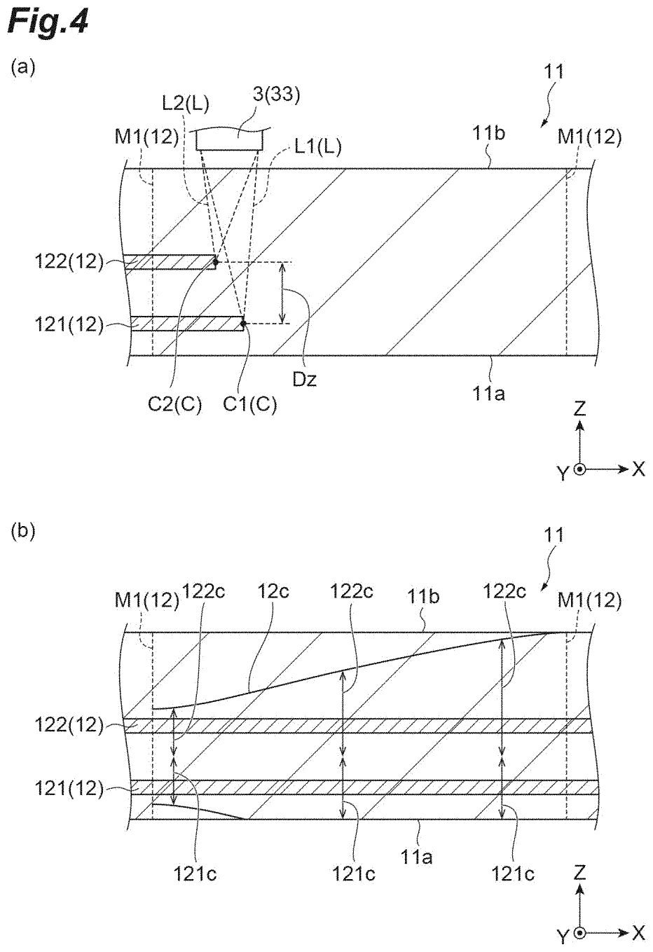

Subsequently, the findings of the inventors of the present invention will be described by comparing processing examples. FIG. 4 is a cross-sectional view illustrating processing according to a first example. In the first example, the converging point C1 is located in front of the converging point C2 in the X direction (distance Dx>0), and the distance Dz between the converging point C1 and the converging point C2 in the Z direction is relatively small. Here, a crack 121c extending from the modified region 121 formed at the converging point C2 is connected to a crack 122c extending from the modified region 122 formed at the preceding converging point C1. As a result, a crack 12c extending over the modified regions 121 and 122 and extending toward the front surface 11a and the back surface 11b is formed.

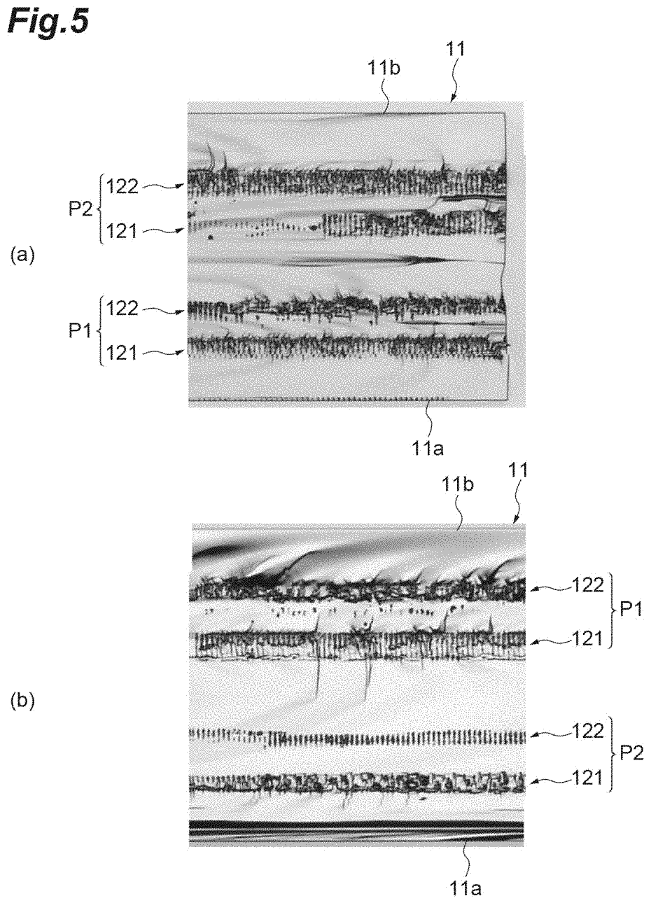

FIG. 5 is a cross-sectional photograph illustrating a processing result according to the first example. FIG. 5(a) is an example of a case where a first irradiation (scan P1) of the laser lights L1 and L2 according to the first example is performed on a side of the object 11 far from the back surface 11b which is the incident surface of the laser lights L1 and L2 (i.e., a side close to the front surface 11a), and a second irradiation (scan P2) of the laser lights L1 and L2 according to the first example is performed on a side close to the back surface 11b. FIG. 5(b) illustrates an example of a case where a first scan P1 according to the first example is performed on the side close to the back surface 11b and a second scan P2 according to a second example is performed on the side far from the back surface 11b.

Here, irradiation conditions of the laser lights L1 and L2 in the scans P1 and P2 were: the frequency is 80 kHz; the processing speed is 530 mm/s; the pulse pitch is 6.625 μm; the pulse width is 400 nsec; and the pulse energy of the converging point C1 and the converging point C2 is 15.40625 μj.

In any case of FIG. 5, the crack 12c illustrated in FIG. 4, particularly, extension amount (crack amount) of the portion of the crack 122c extending from the modified region 122 to the back surface 11b side becomes unstable depending on the position in the X direction. As a result, for example, meandering amount of the crack 12c reaching the back surface 11b increased to 10 μm or more. In addition, an undivided region in which cutting does not occur, and stuffiness in which a part of the other side remains on one divided side of the object 11 have occurred. That is, in these cases, deterioration in processing quality occurred.

In particular, in the first example, a plurality of modified regions 12 extending along the Y direction (line M1) are already formed, and irradiation with the laser lights L1 and L2 is performed so as to straddle the modified regions 12 along the X direction. The crack amount tends to increase from immediately after passing over one modified region 12 (extending along the Y-axis direction) toward another modified region 12 located next to the one modified region 12 in the X direction which is the processing traveling direction.

Then, the crack amount of the crack 12c decreases immediately after passing another modified region 12, and increases again toward further another modified region 12. That is, in this case, the increase and decrease of the crack amount are repeated at the pitch of the modified region 12 extending along the Y direction. As a result, the influence of the destabilization of the crack amount on the processing quality increases. In particular, the smaller the pitch (chip size) of the modified region 12 extending along the Y direction, the more remarkable this influence.

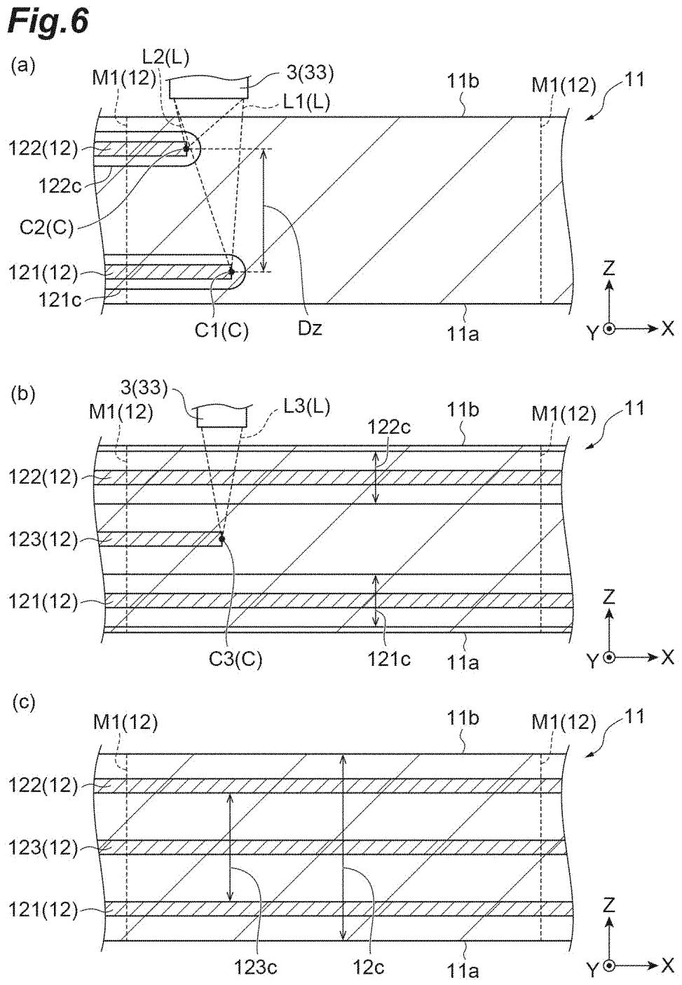

On the other hand, FIG. 6 is a cross-sectional view illustrating processing according to a second example. In the second example, similarly to the first example, the converging point C1 is located in front of the converging point C2 in the X direction (distance Dx>0), but the distance Dz between the converging point C1 and the converging point C2 in the Z direction is relatively large. As a result, as illustrated in FIGS. 6(a) and (b), irradiation with the laser lights L1 and L2 is performed while preventing the crack 121c extending from the modified region 121 and the crack 122c extending from the modified region 122 from being connected to each other.

Then, in the second example, as illustrated in FIGS. 6(b) and (c), by irradiating the object 11 with laser light L3 while positioning a third converging point C3 of the laser light L3 at a position between the converging point C1 and the converging point C2, a crack 123c extending from a modified region 123 formed at the third converging point C3 and extending over the modified region 121 and the modified region 122 is formed. The crack 122c and the crack 121c further extend due to the formation of the crack 123c, so as to form a crack 12c extending from the front surface 11a to the back surface 11b as a whole.

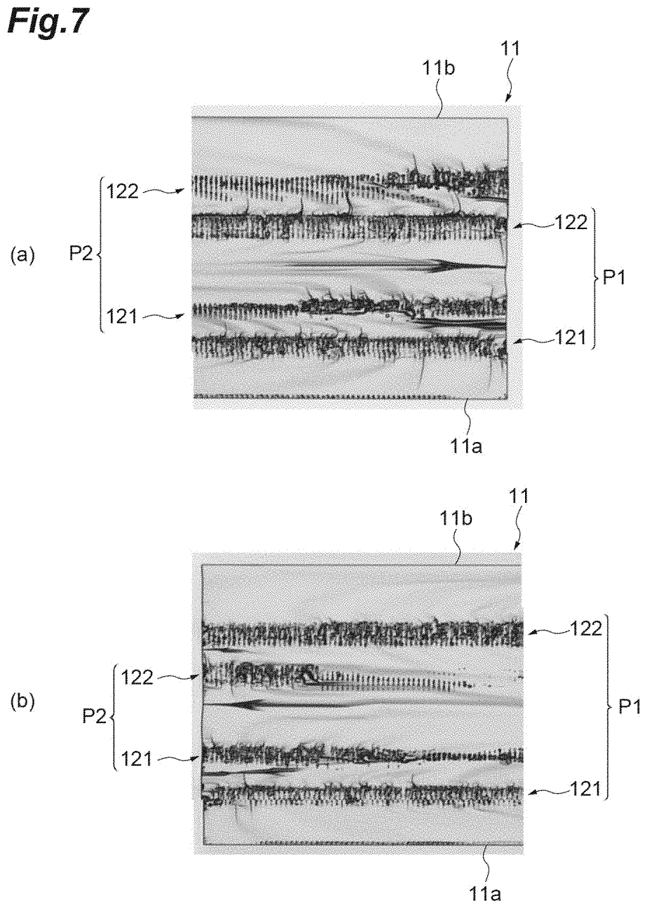

FIG. 7 is a cross-sectional photograph illustrating a processing result according to the second example. FIG. 7(a) is an example of a case where after a first irradiation (scan P1) of the laser lights L1 and L2 according to the second example is performed, a second irradiation (scan P2) of the laser lights L1 and L2 according to the second example is performed while only the converging point C1 is positioned between the position of the converging point C1 and the position of the converging point C2 in the first scan P1. FIG. 7(b) illustrates an example of a case where, after a first scan P1 according to the second example is performed, a second scan P2 according to the second example is performed while both the converging point C1 and the converging point C2 are positioned between the position of the converging point C1 and the position of the converging point C2 in the first scan P1. The irradiation conditions of the laser lights L1 and L2 are similar to those in the first example.

In any case of FIG. 7, the crack amount was stable regardless of the position in the X direction. As a result, for example, the meandering amount of the crack 12c reaching the back surface 11b was 4.5 μm in the case of FIGS. 7(a) and 3.2 μm in the case of FIG. 7(b), which were smaller than those in the first example. As a result, deterioration in processing quality was suppressed.

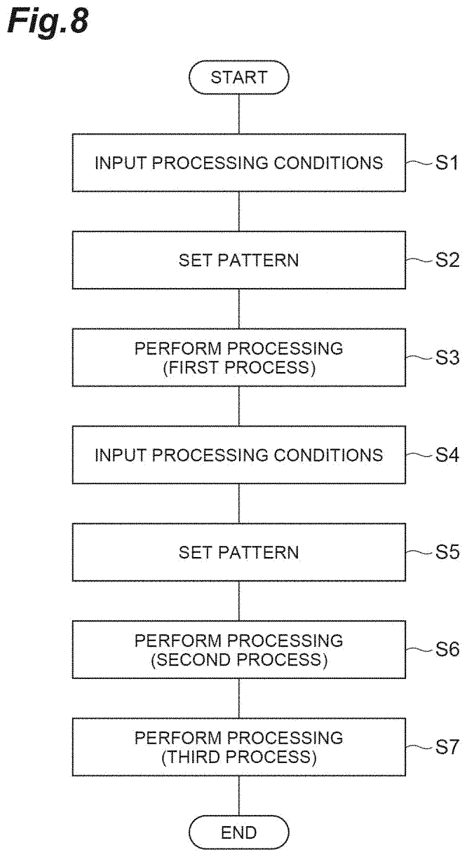

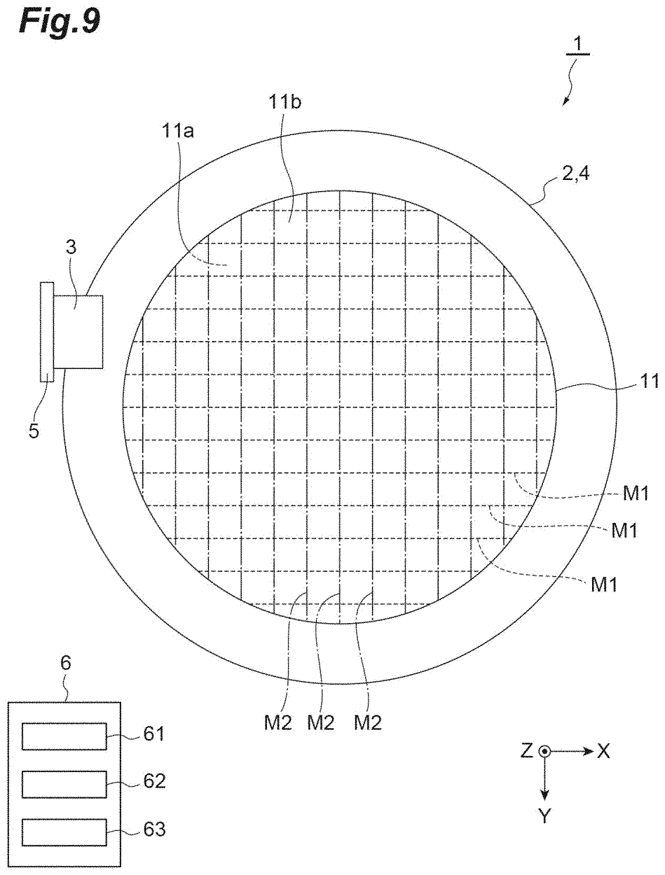

Next, details of the laser processing device will be described with an example of the laser processing method executed by the laser processing device 1. FIG. 8 is a flowchart illustrating an example of a laser processing method according to the present embodiment. Here, as illustrated in FIG. 9, the object 11 is supported by the stage 2 such that the back surface 11b faces the laser irradiation unit 3. A plurality of lines (first lines) M1 and a plurality of lines (second lines) M2 are set in the object 11. The lines M1 and M2 can be set in the control unit 6. As an example, the lines M1 and M2 are virtual lines or specified by coordinates.

The plurality of lines M1 extend in parallel to each other. The plurality of lines M2 extend in parallel to each other. The line M1 and the line M2 extend so as to intersect (be orthogonal to) each other when viewed from the Z direction. That is, the line M2 extends beyond (so as to straddle) the plurality of lines M1 when viewed from the Z direction. Here, since processing along the line M1 is first performed, the object 11 is arranged such that the line M1 is along the X direction (here, the first direction) and the line M2 is along the Y direction (here, the second direction).

In the laser processing device 1 (laser processing method), first, processing conditions for performing processing along the line M1 are input (step S1). More specifically, in step S1, the control unit 6 causes the input receiving unit 63 to display information prompting the input of the processing conditions. The input receiving unit 63 receives the input of the processing conditions.

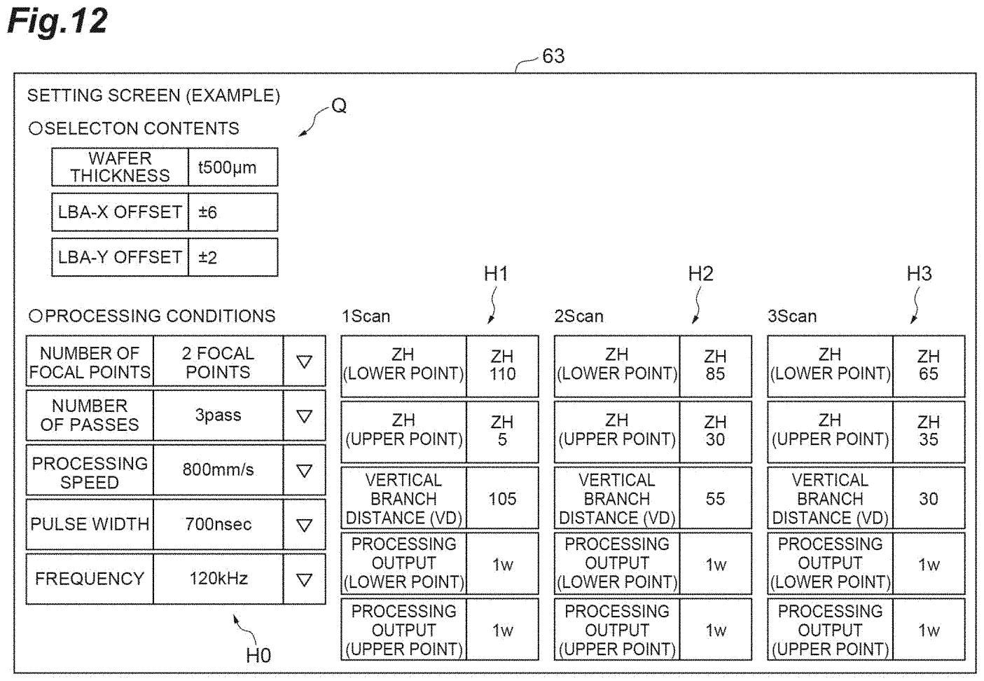

The processing along the line M1 is performed in a situation where the modified region 12 is not formed in the object 11. Therefore, as described above, the influence of the destabilization of the crack amount on the processing quality is relatively small. Therefore, the processing along the line M1 may be performed according to any of the first example and the second example described above, and is arbitrary. Therefore, the processing conditions that can be input in step S1 are also arbitrary, but as an example, processing conditions similar to the processing conditions illustrated in FIG. 12 to be described later (processing conditions according to the second example) can be input.

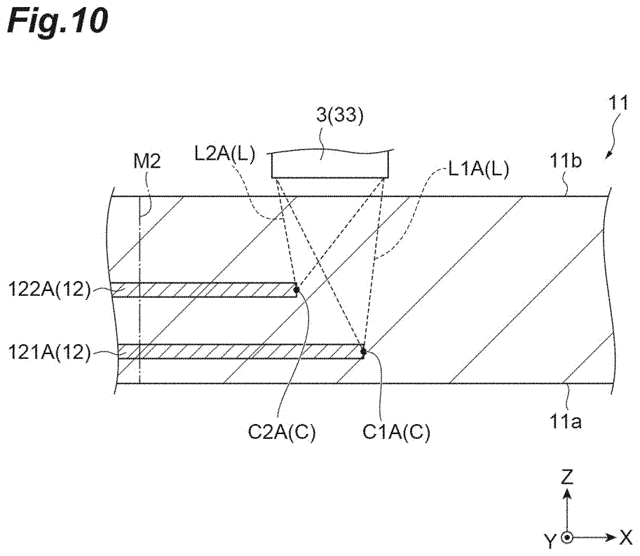

Subsequently, the control unit 6 sets (generates) a modulation pattern to be displayed on the spatial light modulator 32 according to the processing conditions input in step S1 (step S2). Here, the control unit 6 sets a modulation pattern including a branching pattern for branching the laser light L into a plurality of beams. As a result, the laser light L that has passed through the spatial light modulator 32 on which the modulation pattern is displayed is branched into laser light L1A and laser light L2A as illustrated in FIG. 10, and a converging point (a fifth converging point) C1A and a converging point (a sixth converging point) C2A of the laser light L1A are formed.

Subsequently, as illustrated in FIG. 10, processing along the line M1 is performed (step S3, a first process, a first step). Schematically, by controlling the laser irradiation unit 3 and the drive unit 5 (and/or the drive unit 4), the control unit 6 forms the modified region 12 along the line M1 by irradiating the object 11 with the laser light L while relatively moving the converging point C along the line M1 (laser light irradiation step).

More specifically, here, by controlling the laser irradiation unit 3 and the drive unit 5 (and/or the drive unit 4), the control unit 6 irradiates the object 11 with the laser lights L1A and L2A while forming the converging point C1A of the laser light L1A and the converging point C2A of the laser light L2A located closer to the back surface 11b side of the object 11 than the converging point C1A and at the same time relatively moving the converging point C1A and the converging point C2A along the line M1. As a result, a modified region 121A corresponding to the laser light L1A and the converging point C1A and a modified region 122A corresponding to the laser light L2A and the converging point C2A are formed as the modified region 12.

In particular, in the processing along the line M1, arbitrary processing can be performed as described above, but processing according to the second example can also be performed. In such a case, first, by controlling the laser irradiation unit 3 and the drive unit 5 (and/or the drive unit 4), the control unit 6 can execute a step (a fourth process) of forming the modified regions 121A and 122A along the line M by irradiating the object 11 with the laser lights L1A and L2A while relatively moving the converging point C1A and the converging point C2A along the line M1 so that the crack extending from the modified region 121A formed at the converging point C1A and the crack extending from the modified region 122A formed at the converging point C2A are not connected to each other.

Thereafter, by controlling the laser irradiation unit 3 and the drive unit 5 (and/or the drive unit 4), the control unit 6 can further execute a step (a fifth process) of forming the modified region 12 at a seventh position between the position (a fifth position) of the converging point C1A and the position (a sixth position) of the converging point C2A in the Z direction along the line M1 and forming a crack over the modified region 121A formed at the fifth position and the modified region 122A formed at the sixth position by irradiating the object 11 with the laser light L while forming a converging point (a seventh converging point) of the laser light L at the seventh position and at the same time relatively moving the seventh converging point along the line M1.

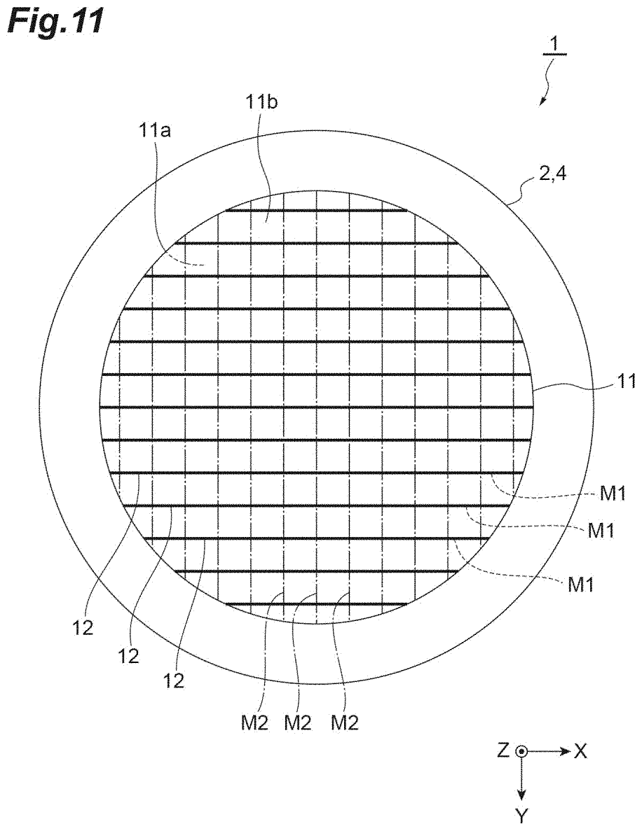

The above first process is executed for all the lines M1. As a result, as illustrated in FIG. 11, the modified region 12 is formed along all the lines M1. As a result, in the subsequent processing along the line M2, the irradiation of the laser light L is performed beyond (so as to straddle) the modified region 12 already formed along the line M1.

In the subsequent step, processing along the line M2 is performed. Therefore, the control unit 6 rotates the stage 2 by controlling the drive unit 4 to arrange the object 11 such that the line M2 is along the X direction. In the processing along the line M2, at least the laser light L is branched into laser lights L1 and L2, and the laser lights L1 and L2 are irradiated (scanned) along the line M2 while moving the respective converging point C1 and converging point C2 relative to the object 11.

Subsequently, processing conditions for processing along the line M2 are input (step S4). More specifically, in step S4, the control unit 6 causes the input receiving unit 63 to display information prompting the input of the processing conditions. The input receiving unit 63 receives the input of the processing conditions. At this time, the input receiving unit 63 receives at least the input of the distance Dz. The input receiving unit 63 also receives the inputs of various other processing conditions. This point will be described in detail.

FIG. 12 is a diagram illustrating an example of a setting screen displayed on the input receiving unit. As illustrated in FIG. 12, here, as selection contents Q, inputs of wafer thickness, LBA-X offset, and LBA-Y offset are received (input of the distance Dx may be further received). The LBA-X offset is an offset amount in the X direction (direction along the line M2) between the center of a spherical aberration correction pattern and the center of an entrance pupil plane of the condenser lens 33, among various patterns displayed on the spatial light modulator 32. Similarly, the LBA-Y offset is an offset amount in the Y direction (direction intersecting the line M2) between the center of the spherical aberration correction pattern and the center of the entrance pupil plane of the condenser lens 33.

The input receiving unit 63 receives inputs of number of focal points, number of passes, processing speed, pulse width, and frequency as basic processing conditions HO. The number of focal points is the number of branches of the laser light L by the spatial light modulator 32, and is 2 here. The number of passes is the number of times of a second process (to be described later) for one line M2, and is the number of times of scans of the laser lights L1 and L2. The modified regions 12 of the number of rows corresponding to “the number of focal points×the number of passes” are formed in the Z direction. The processing speed is the speed of relative movement of the converging point C1 and the converging point C2 with respect to the object 11.

Furthermore, the input receiving unit 63 receives inputs of detailed processing conditions in each scan. Here, since 3 is input as the number of passes, the input receiving unit 63 receives inputs of processing conditions H1 to H3 of each of the three scans. In the processing conditions H1 to H3, ZH (lower point) corresponds to the position of the converging point C1 in the Z direction. ZH (upper point) corresponds to the position of the converging point C2 in the Z direction. Since the ZH (lower point) and the ZH (upper point) are based on the back surface 11b that is the incident surface of the laser lights L1 and L2, the larger the numerical value, the farther from the back surface 11b.

Vertical branch distance (VD) is the distance Dz and corresponds to the difference between the ZH (lower point) and the ZH (upper point). Processing output (lower point) is the output of the laser light L1, and processing output (upper point) is the output of the laser light L2. Here, the same value is input for the processing output (lower point) and the processing output (upper point). Therefore, the output ratio between the laser light L1 and the laser light L2 is set to 50:50.

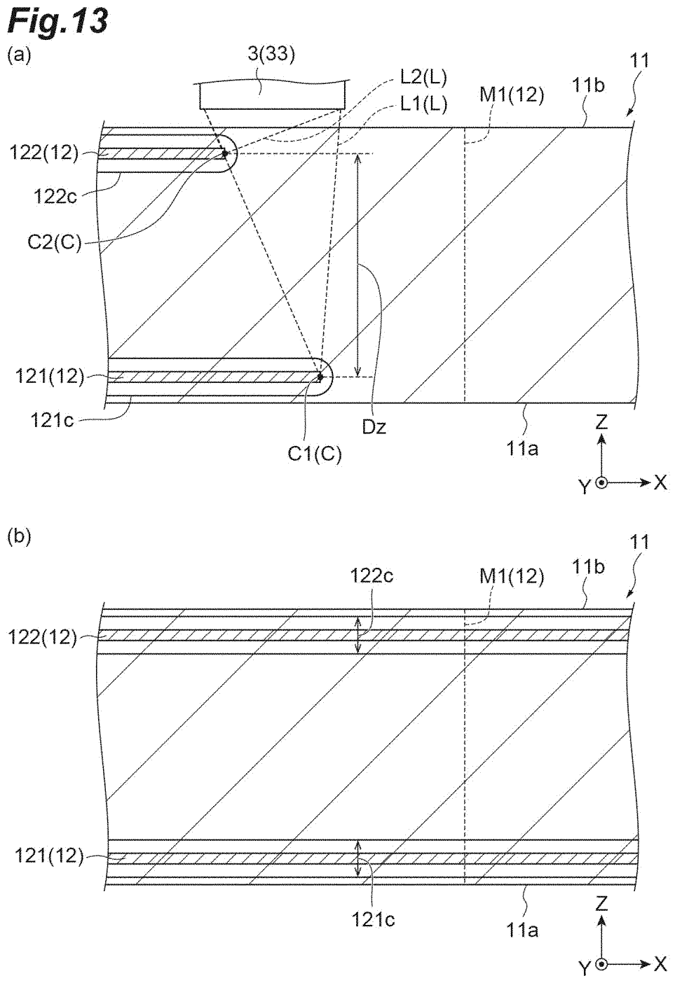

In the subsequent step, the control unit 6 sets (generates) the modulation pattern to be displayed on the spatial light modulator 32 according to the processing condition input in step S4 (step S5). Here, the control unit 6 sets a modulation pattern including a branching pattern for branching the laser light L into a plurality of beams. As a result, as illustrated in FIG. 13 and the like, the laser light L that has passed through the spatial light modulator 32 on which the modulation pattern is displayed is branched into laser light L1 and laser light L2, and a converging point (a first converging point) C1 and a converging point (a second converging point) C2 of the laser light L1 are formed.

Subsequently, processing along the line M2 is actually performed (step S6, a second process, a second step). Schematically, by controlling the laser irradiation unit 3 and the drive unit 5 (and/or the drive unit 4), the control unit 6 forms the modified region 12 along the line M2 by irradiating the object 11 with the laser light L while relatively moving the converging point C along the line M2 (laser light irradiation step).

More specifically, first, a first scan is performed. That is, as illustrated in FIG. 13(a), as in the second example, by controlling the laser irradiation unit 3 and the drive unit 5 (and/or the drive unit 4), the control unit 6 forms the modified region 12 along the line M2 by irradiating the object 11 with the laser lights L1 and L2 while forming the converging point C1 of the laser light L1 and the converging point C2 of the laser light L2 located closer to the back surface 11b than the converging point C1 and at the same time relatively moving the converging point C1 and the converging point C2 along the line M2 so that the crack 121c extending from the modified region 121 formed at the converging point C1 and the crack 122c extending from the modified region 122 formed at the converging point C2 are not connected to each other.

Here, the control unit 6 makes the distance Dz between the converging point C1 and the converging point C2 to become the input value of the processing conditions H1 corresponding to the first scan by adjusting the branching pattern to be displayed on the spatial light modulator 32 (that is, by controlling the laser irradiation unit 3).

Furthermore, here, as an example, the control unit 6 positions the converging point C1 in front of the converging point C2 in the X direction, which is the relative movement direction of the converging point C1 and the converging point C2 and which is the processing traveling direction, by adjusting the branching pattern to be displayed on the spatial light modulator 32 (that is, by controlling the laser irradiation unit 3). That is, here, the distance Dx is set to be larger than 0.

However, the control unit 6 may cause the converging point C1 and the converging point C2 to coincide with each other in the X direction by adjusting the branching pattern to be displayed on the spatial light modulator 32 (that is, by controlling the laser irradiation unit 3), according to the input. That is, here, the distance Dx may be set to 0.

As described above, the modified region 12 is already formed along the line M1 in the object 11. Therefore, in the first scan, the laser lights L1 and L2 are irradiated beyond (so as to straddle) the modified region 12 that has already been formed. As a result, as illustrated in FIG. 13(b), the modified regions 121 and 122 are formed so that the crack 121c and the crack 122c are not connected to each other over the entire line M2. Here, the crack 121c does not reach the front surface 11a, and the crack 122c does not reach the back surface 11b.

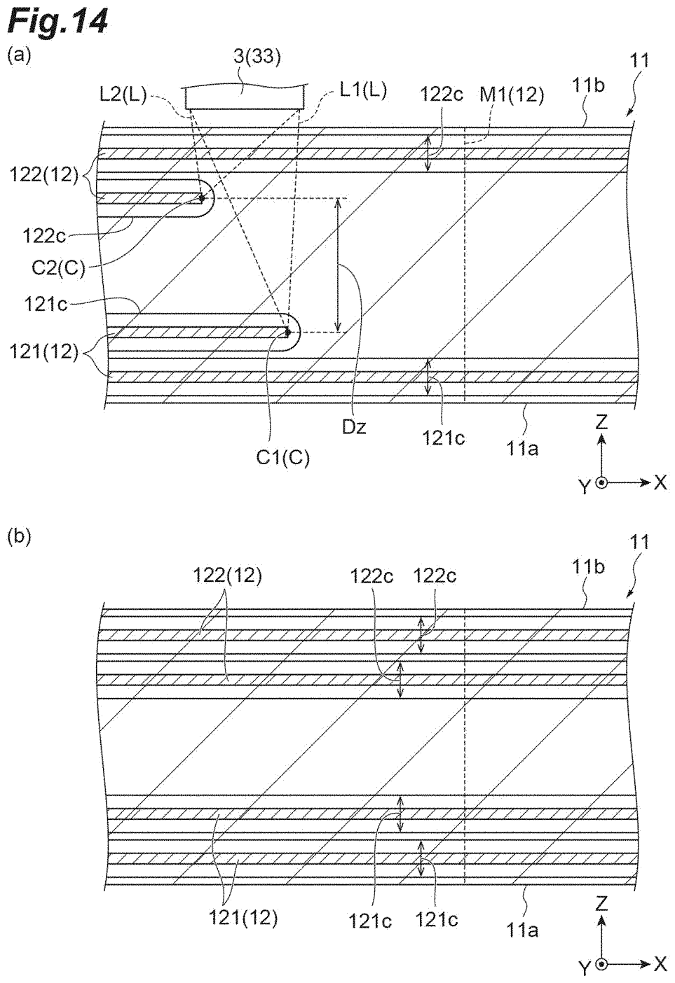

Subsequently, a second scan is performed (step S6, the second process, the second step). That is, as illustrated in FIG. 14(a), as in the second example, by controlling the laser irradiation unit 3 and the drive unit 5 (and/or the drive unit 4), the control unit 6 forms the modified region 12 along the line M2 by irradiating the object 11 with the laser lights L1 and L2 while forming the converging point C1 of the laser light L1 and the converging point C2 of the laser light L2 located closer to the back surface 11b than the converging point C1 and at the same time relatively moving the converging point C1 and the converging point C2 along the line M2 so that the crack 121c extending from the modified region 121 formed at the converging point C1 and the crack 122c extending from the modified region 122 formed at the converging point C2 are not connected to each other.

Here, the control unit 6 makes the distance Dz between the converging point C1 and the converging point C2 to become the input value of the processing conditions H2 corresponding to the second scan by adjusting the branching pattern to be displayed on the spatial light modulator 32 (that is, by controlling the laser irradiation unit 3). In particular, here, the control unit 6 performs the second scan in a state where both the converging point C1 and the converging point C2 are located between the position of the converging point C1 (the modified region 121) in the first scan and the position of the converging point C2 (the modified region 122) in the first scan. That is, the distance Dz in the second scan is made smaller than the distance Dz in the first scan.

Furthermore, here, as an example, the control unit 6 positions the converging point C1 in front of the converging point C2 in the X direction, which is the relative movement direction of the converging point C1 and the converging point C2 and which is the processing traveling direction, by adjusting the branching pattern to be displayed on the spatial light modulator 32 (that is, by controlling the laser irradiation unit 3). That is, here, the distance Dx is set to be larger than 0.

However, the control unit 6 may cause the converging point C1 and the converging point C2 to coincide with each other in the X direction by adjusting the branching pattern to be displayed on the spatial light modulator 32 (that is, by controlling the laser irradiation unit 3), according to the input. That is, here, the distance Dx may be set to 0.

In addition, also here, the laser lights L1 and L2 are irradiated beyond (so as to straddle) the modified region 12 that has already been formed. As a result, as illustrated in FIG. 14(b), the modified regions 121 and 122 are formed between the modified regions 121 and 122 formed in the first scan so that the crack 121c and the crack 122c are not connected to each other over the entire line M2. Note that, here, the crack 121c formed in the first scan and the crack 121c formed in the second scan are not connected (but may be connected) to each other. In addition, the crack 122c formed in the first scan and the crack 122c formed in the second scan are not connected to each other. The crack 121c has not reached the front surface 11a, and the crack 122c has not reached the back surface 11b.

In the subsequent step, by controlling the laser irradiation unit 3 and the drive unit 5 (and/or the drive unit 4), the control unit 6 forms the modified region 12 along the line M2 by further irradiating the object 11 with the laser light L while relatively moving the converging point C along the line M2.

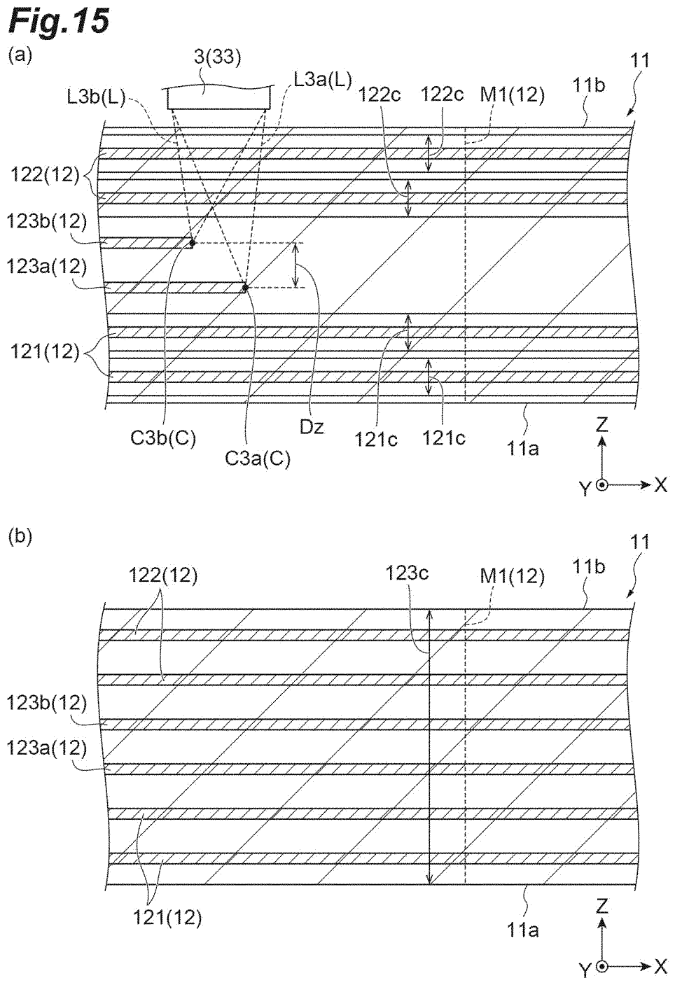

More specifically, the control unit 6 performs a third scan (step S7, a third process, a third step). Here, as illustrated in FIG. 15(a), the control unit 6 branches the laser light L into laser lights L3a and L3b, and forms a converging point (a third converging point) C3a of the laser light L3a and a converging point (a fourth converging point) C3b of the laser light L3b located closer to the back surface 11b side than the converging point C3a.

Then, by controlling the laser irradiation unit 3 and the drive unit 5 (and/or the drive unit 4), the control unit 6 irradiates the object 11 with the laser lights L3a and L3b while forming the converging points C3a and C3b of the laser lights L3a and L3b at a third position between the position (a first position) of the converging point C1 and the position (a second position) of the converging point C2 in the Z direction in the second scan and at the same time relatively moving the converging points C3a and C3b along the line M2. As a result, as illustrated in FIG. 15(b), modified regions 123a and 123b are formed at the third position along the line M2, and a crack 123c extending over the modified region 121 formed at the first position and the modified region 122 formed at the second position and extending toward the front surface 11a and the back surface 11b is formed.

Here, the control unit 6 makes the distance Dz between the converging point C3a and the converging point C3b to become the input value of the processing conditions H3 corresponding to the third scan by adjusting the branching pattern to be displayed on the spatial light modulator 32 (that is, by controlling the laser irradiation unit 3). In particular, here, the control unit 6 performs the third scan in a state where both the converging point C3a and the converging point C3b are located between the first position (modified region 121) of the converging point C1 in the second scan and the second position (modified region 122) of the converging point C2 in the second scan. That is, the distance Dz is made smaller than the distance Dz in the first scan and the distance Dz in the second scan.

Furthermore, here, as an example, the control unit 6 positions the converging point C3a in front of the converging point C3b in the X direction, which is the relative movement direction of the converging point C3a and the converging point C3b and which is the processing traveling direction, by adjusting the branching pattern to be displayed on the spatial light modulator 32 (that is, by controlling the laser irradiation unit 3). That is, here, the distance Dx is set to be larger than 0.

However, the control unit 6 may cause the converging point C3a and the converging point C3b to coincide with each other in the X direction by adjusting the branching pattern to be displayed on the spatial light modulator 32 (that is, by controlling the laser irradiation unit 3), according to the input. That is, here, the distance Dx may be set to 0. The second process and the third process described above are executed for all the lines M2. As a result, the modified region 12 is formed along all the lines M1 and the lines M2. As a result, the object 11 can be cut along the line M1 and the line M2.

As described above, in the laser processing device 1 and the laser processing method thereof, the line M1 and the line M2 extending beyond the line M1 are set for the object 11. The laser light L is irradiated along the line M1 to form the modified region 12, and then the laser light L is irradiated along the line M2 to form the modified region 12. When irradiating the laser light L along the line M2, at least two converging points C1 and C2 are formed in the Z direction. Therefore, the processing speed is improved. On the other hand, in the laser processing device 1 and the laser processing method thereof, irradiation of the laser light L is generated so as to straddle the modified region 12 and the like already formed along the line M1. Therefore, it is important to suppress the destabilization of the crack.

Therefore, in the laser processing device 1 and the laser processing method thereof, after the modified region 12 is formed along the line M1, first, the modified regions 121 and 122 are formed along the line M2 by irradiating the object 11 with the laser lights L1 and L2 while relatively moving the converging point C1 and the converging point C2 along the line M2 so that the crack 121c extending from the modified region 121 formed at the converging point C1 of the laser light L1 and the crack 122c extending from the modified region 122 formed at the converging point C2 of the laser light L2 are not connected to each other. Thereafter, by irradiating the object 11 with the laser light L3a while forming the converging point C3a of the laser light L3a at the third position between the first position of the converging point C1 and the second position of the converging point C2 and at the same time relatively moving the converging point C3a along the line M2, the modified region 123a is formed along the line M2 at the third position, and the crack 123c extending over the modified region 121 and the modified region 122 is formed. As a result, destabilization of the entire crack amount is suppressed. Therefore, deterioration in processing quality is suppressed.

Further, in the laser processing device 1, in the second process, by controlling the laser irradiation unit 3, the control unit 6 can position the converging point C1 in front of the converging point C2 in the relative movement direction of the converging point C1 and the converging point C2. In such a case, it is possible to increase the extension amount of the cracks 121c and 122c from the modified regions 121 and 122 formed at the converging point C1 and the converging point C2, respectively. As a result, the number of rows of the modified regions 12 required in the Z direction is reduced, and the processing speed is improved.

On the other hand, in the laser processing device 1, in the second process, by controlling the laser irradiation unit 3, the control unit 6 may cause the converging point C1 and the converging point C2 to coincide with each other in the X direction. In such a case, it is possible to reduce the extension amount of the cracks 121c and 122c from the modified regions 121 and 122 formed at the converging point C1 and the converging point C2, respectively. As a result, it is possible to reliably suppress the crack 121c extending from the modified region 121 formed by the converging point C1 and the crack 122c extending from the modified region 122 formed by the converging point C2 from being connected.

In the laser processing device 1, in the third process, by controlling the laser irradiation unit 3 and the drive unit 5 (and/or the drive unit 4), the control unit 6 irradiates the object 11 with the laser lights L3a and L3b while forming the converging point C3a and the converging point C3b of the laser light L3b located closer to the back surface 11b side than the converging point C3a and at the same time relatively moving the converging point C3a and the converging point C3b along the line M2. Therefore, the processing speed is further improved.

Furthermore, in the laser processing device 1, in the first process, by controlling the laser irradiation unit 3 and the drive unit 5 (and/or the drive unit 4), the control unit 6 irradiates the object 11 with the laser lights L1A and L2A while forming the converging point C1A of the laser light L1A and the converging point C2A of the laser light L2A located closer to the back surface 11b side than the converging point C1A and at the same time relatively moving the converging point C1A and the converging point C2A along the line M1. Therefore, the processing speed is further improved.

Furthermore, in the laser processing device 1, in the first process, by controlling the laser irradiation unit 3 and the drive unit 5 (and/or the drive unit 4), the control unit 6 may execute the fourth process of forming the modified regions 121A and 122A along the line M1 by irradiating the object 11 with the laser lights L1A and L2A while relatively moving the converging point C1A and the converging point C2A along the line M2 so that the crack extending from the modified region 121A formed at the converging point C1A and the crack extending from the modified region 122A formed at the converging point C2A are not connected to each other.

At this time, after the fourth process, by controlling the laser irradiation unit 3 and the drive unit 5 (and/or the drive unit 4), the fifth process of forming the modified region 12 along the line M1 at the seventh position between the fifth position of the converging point C1A and the sixth position of the converging point C2A in the Z direction and forming the crack over the modified region 121A and the modified region 122A may be executed by irradiating the object 11 with the laser light L while forming a converging point of the laser light L at the seventh position and at the same time relatively moving the converging point along the line M1. In such a case, for the same reason as described above, it is possible to improve the processing speed and suppress deterioration in processing quality also in the first process.

The above embodiment describes one aspect of one aspect of the present disclosure. Accordingly, the present invention may be modified without being limited to the examples described above.

For example, in the above embodiment, the case where three scans are performed through the second process and the third process has been described. However, the number of times of scans in the second process and the third process is arbitrary.

Further, in the above embodiment, in the third process, irradiation with the laser lights L3a and L3b is performed in a state where both the converging points C3a and C3b of the laser lights L3a and L3b are positioned between the modified regions 121 and 122 formed in the second process. However, in the third process, the crack extending over the modified regions 121 and 122 may be formed by irradiating the laser light while positioning at least one converging point between the modified regions 121 and 122 formed in the second process.

In addition, the relationship between the distances Dz at the time of each scan in the second process and the third process is not limited to the above examples.

Furthermore, in the above embodiment, the control unit 6 (input receiving unit 63) displays information prompting the input of each value illustrated in FIG. 12 and receives the input of each value. However, the control unit 6 may cause the input receiving unit 63 to display information prompting input of a part of the values illustrated in FIG. 12, and when the input receiving unit 63 receives the input of the part, the control unit 6 may propose another part of the processing conditions.

As an example, the control unit 6 may be configured to cause the input receiving unit 63 to display the selection contents Q and information prompting the input of each value included in the basic processing conditions HO, and to suggest the optimal processing conditions H1 to H3 when the input receiving unit 63 receives the input.

Incidentally, in the example of FIG. 7(a), in the scan P2, one modified region 121 is formed between the modified regions 121 and 122 formed in the scan P1, and the other modified region 122 is formed outside the modified regions 121 and 122 (that is, the modified regions are alternately formed in the scans P1 and P2). The formation of such modified regions can be similarly performed in the third process illustrated in FIG. 15. That is, FIG. 15 illustrates an example in which the pair of modified regions 123a and 123b are formed by the third processing between the modified regions 121 and 122 formed by the second process, but for example, in the third processing, the modified region 123b may be formed outside the modified regions 121 and 122 while forming the modified region 123a between the modified regions 121 and 122. In other words, in the third process, the crack may be formed over the modified regions 121 and 122 by forming at least one row of modified region between the modified regions 121 and 122 formed in the second process.

Here, it has been described as above that, when the modified region 12 is formed along the plurality of lines M1 and then the modified region 12 is formed in the line M2 set to straddle the line M1, since the portion where the crack amount decreases and the portion where the crack amount increases repeatedly occur in a short period (the pitch of formation of the modified region 12 and the like), the destabilization of the entire crack amount has relatively large influence on the processing quality, and thus it is important to adopt the characteristic irradiation method of laser light.

However, in a case where only a portion of the object 11 where the modified region 12 is not formed is irradiated with the laser light L, such as the case where the modified region 12 is formed along the line M1, the crack amount may change from the irradiation start position to the irradiation end position of the laser light L; therefore, by adopting the characteristic laser light irradiation method described above, it is possible to realize improvement in processing speed and suppression of deterioration in processing quality. That is, the above characteristic laser light irradiation method can be adopted regardless of which of the lines M1 and M2 is processed. Therefore, the following matters are additionally described.

(Supplementary note) The laser processing device 1 is a laser processing device for forming a modified region 12 by irradiating an object 11 with laser light L, and includes a stage 2 configured to support the object 11, a laser irradiation unit 3 configured to irradiate the object 11 supported by the stage 2 with the laser light L, drive units 4 and 5 that move at least one of the stage 2 and the laser irradiation unit 3 such that a converging point C of the laser light L relatively moves with respect to the object 11, and a control unit 6 that controls the laser irradiation unit 3 and the drive units 4 and 5. By controlling the laser irradiation unit 3 and the drive units 4 and 5, the control unit 6 can execute a process of forming the modified regions 121 and 122 by irradiating the object 11 with the laser lights L1 and L2 while forming the converging point C1 of the laser light L1 and the converging point C2 of the laser light L2 located closer to the back surface 11b side than the converging point C1 and at the same time relatively moving the converging points C1 and C2 so that a crack 121c extending from the modified region 122 formed at the converging point C1 and a crack 122c extending from the modified region 122 formed at the converging point C2 are not connected to each other.

After the process, by controlling the laser irradiation unit 3 and the drive units 4 and 5, the control unit 6 can execute another process of forming the modified region at a third position between a first position of the converging point C1 and a second position of the converging point C2 in the direction intersecting the back surface 11b and forming a crack over the modified region 121 formed at the first position and the modified region 122 formed at the second position by irradiating the object 11 with the laser light L3a while forming a converging point C3a of the laser light L3a at the third position and at the same time relatively moving the converging point C3a.

### INDUSTRIAL APPLICABILITY

Provided are a laser processing device and a laser processing method capable of achieving both improvement in processing speed and suppression of deterioration in processing quality.

### REFERENCE SIGNS LIST

1 Laser processing device

2 Stage (support portion)

3 Laser irradiation unit

4 Drive unit (moving mechanism)

5 Drive unit (moving mechanism)

6 Control unit

11 Object

12, 121, 122, 123a, 123b Modified region

12c, 121c, 122c Crack

C Converging point

C1 Converging point (first converging point)

C2 Converging point (second converging point)

C3a, C3b Converging point (third converging point)

L, L1, L2, L3a, L3b Laser light

M1 Line (first line)

M2 Line (second line)

1. A laser processing device for forming a modified region by irradiating an object with laser light, the laser processing device comprising:
a support portion configured to support the object;
a laser irradiation unit configured to irradiate the object supported by the support portion with the laser light;
a moving mechanism configured to move at least one of the support portion and the laser irradiation unit such that a converging point of the laser light relatively moves with respect to the object; and
a control unit configured to control the laser irradiation unit and the moving mechanism,
wherein
a first line extending along a first direction and a second line extending along a second direction intersecting the first direction and extending beyond the first line when viewed from a direction intersecting an incident surface of the laser light are set in the object, and
the control unit
performs, by controlling the laser irradiation unit and the moving mechanism, a first process of forming the modified region along the first line by irradiating the object with the laser light while relatively moving the converging point along the first line,
performs, after the first process, by controlling the laser irradiation unit and the moving mechanism, a second process of forming the modified region along the second line by irradiating the object with the laser light while forming a first converging point of the laser light and a second converging point of the laser light located closer to an incident surface side of the object than the first converging point and at the same time relatively moving the first converging point and the second converging point along the second line so that a crack extending from the modified region formed at the first converging point and a crack extending from the modified region formed at the second converging point are not connected to each other, and
performs, after the second process, by controlling the laser irradiation unit and the moving mechanism, a third process of forming the modified region along the second line at a third position between a first position of the first converging point and a second position of the second converging point in a direction intersecting the incident surface and forming a crack over the modified region formed at the first position and the modified region formed at the second position by irradiating the object with the laser light while forming a third converging point of the laser light at the third position and at the same time relatively moving the third converging point along the second line.

2. The laser processing device according to claim 1, wherein
in the second process, by controlling the laser irradiation unit, the control unit positions the first converging point in front of the second converging point in the relative movement direction of the first converging point and the second converging point.

3. The laser processing device according to claim 1, wherein
in the second process, by controlling the laser irradiation unit, the control unit causes the first converging point and the second converging point to coincide with each other in the relative movement direction of the first converging point and the second converging point.

4. The laser processing device according to claim 1, wherein
in the third processing, by controlling the laser irradiation unit and the moving mechanism, the control unit irradiates the object with the laser light while forming the third converging point and a fourth converging point of the laser light located closer to the incident surface side than the third converging point and at the same time relatively moving the third converging point and the fourth converging point along the second line.

5. The laser processing device according to claim 1, wherein
in the first process, by controlling the laser irradiation unit and the moving mechanism, the control unit irradiates the object with the laser light while forming a fifth converging point of the laser light and a sixth converging point of the laser light located closer to the incident surface side of the object than the fifth converging point and at the same time relatively moving the fifth converging point and the sixth converging point along the first line.

6. The laser processing device according to claim 5, wherein
in the first process, the control unit
performs, by controlling the laser irradiation unit and the moving mechanism, a fourth process of forming the modified region along the first line by irradiating the object with the laser light while relatively moving the fifth converging point and the sixth converging point along the first line so that a crack extending from the modified region formed at the fifth converging point and a crack extending from the modified region formed at the sixth converging point are not connected to each other; and
performs, after the fourth process, by controlling the laser irradiation unit and the moving mechanism, a fifth process of forming the modified region along the first line at a seventh position between a fifth position of the fifth converging point and a sixth position of the sixth converging point in a direction intersecting the incident surface and forming a crack over the modified region formed at the fifth position and the modified region formed at the sixth position by irradiating the object with the laser light while forming a seventh converging point of the laser light at the seventh position and at the same time relatively moving the seventh converging point along the first line.

7. A laser processing method for forming a modified region by irradiating an object with laser light, the laser processing method comprising
a laser light irradiation step of irradiating the object with the laser light while relatively moving a converging point of the laser light with respect to the object to form the modified region,
wherein
a first line extending along a first direction and a second line extending along a second direction intersecting the first direction and extending beyond the first line when viewed from a direction intersecting an incident surface of the laser light are set in the object, and
the laser light irradiation step includes:
a first step of forming the modified region along the first line by irradiating the object with the laser light while relatively moving the converging point along the first line;
a second step of forming, after the first step, the modified region along the second line by irradiating the object with the laser light while forming a first converging point of the laser light and a second converging point of the laser light located closer to an incident surface side of the object than the first converging point and at the same time relatively moving the first converging point and the second converging point along the second line so that a crack extending from the modified region formed at the first converging point and a crack extending from the modified region formed at the second converging point are not connected to each other; and
a third step of forming, after the second step, the modified region along the second line at a third position between a first position of the first converging point and a second position of the second converging point in a direction intersecting the incident surface and forming a crack over the modified region formed at the first position and the modified region formed at the second position by irradiating the object with the laser light while forming a third converging point of the laser light at the third position and at the same time relatively moving the third converging point along the second line.

8. A laser processing device for forming a modified region by irradiating an object with laser light, the laser processing device comprising:
a support portion configured to support the object;
a laser irradiation unit configured to irradiate the object supported by the support portion with the laser light;
a moving mechanism configured to move at least one of the support portion and the laser irradiation unit such that a converging point of the laser light relatively moves with respect to the object; and
a control unit configured to control the laser irradiation unit and the moving mechanism,
wherein
the control unit
performs, by controlling the laser irradiation unit and the moving mechanism, a process of forming the modified region by irradiating the object with the laser light while forming a first converging point of the laser light and a second converging point of the laser light located closer to an incident surface side of the laser light on the object than the first converging point and at the same time relatively moving the first converging point and the second converging point so that a crack extending from the modified region formed at the first converging point and a crack extending from the modified region formed at the second converging point are not connected to each other, and
performs, after the above process, by controlling the laser irradiation unit and the moving mechanism, another process of forming the modified region at a third position between a first position of the first converging point and a second position of the second converging point in a direction intersecting the incident surface and forming a crack over the modified region formed at the first position and the modified region formed at the second position by irradiating the object with the laser light while forming a third converging point of the laser light at the third position and at the same time relatively moving the third converging point.
